(19) United States
(12) Patent Application Publication
(10) Pub. No.: US 2008/0278208 A1
(43) Pub. Date: Nov. 13, 2008

(54) DATA OUTPUT CIRCUIT OF SEMICONDUCTOR MEMORY APPARATUS

(75) Inventor: Hun Sam Jung, Ichon-shi (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR INC., Ichon (KR)

(21) Appl. No.: 11/962,057

(22) Filed: Dec. 20, 2007

(30) Foreign Application Priority Data
May 11, 2007 (KR) 10-2007-0046237

(51) Int. Cl. H03K 5/12

(52) U.S. Cl. 327/170

(57) ABSTRACT

A data output circuit includes a data output clock signal generating unit that generates a rising data output clock signal and a rising latch signal from a rising clock signal in response to a falling latch signal, and generates a falling data output clock signal and the falling latch signal from a falling clock signal in response to the rising latch signal; and a data output pre-driver that drives a rising data in response to the rising data output clock signal, and drives a falling data in response to the falling data output clock signal.

### CROSS-REFERENCE TO RELATED PATENT APPLICATION

This application claims the benefit under 35 U.S.C 119(a) of Korean Patent Application No. 10-2007-0046237, filed on May 11, 2007, in the Korean Intellectual Property Office, the disclosure of which is incorporated herein in its entirety by reference as if set forth in full.

### BACKGROUND

1. Technical Field

The embodiments described herein relate to a semiconductor memory apparatus, and more particularly, to a data output circuit for a semiconductor memory apparatus that is capable of stably operating at a high processing speed.

2. Related Art

Conventional semiconductor memory apparatus, such as DDR SDRAMs (double data rate synchronous dynamic random access memories), use a DLL (delay locked loop) circuit, to generate a rising clock signal and a falling clock signal used for high speed data output. Data is often output on the rising edge of the generated clock signals. A data output circuit provided in the semiconductor memory apparatus includes a data output clock generating unit that generates a rising data output clock signal and a falling data output clock signal, which are often pulse signals having a short high-level period, from the rising clock signal and the falling clock signal, respectively.

A pre-driver circuit is often used to drive a rising data in synchronization with the rising data output clock signal and a falling data in synchronization with the falling data output clock signal. The data driven by the pre-driver is driven a main driver again, and is then output through a data pad.

FIG. 1 is a diagram illustrating an exemplary data output circuit. As shown in FIG. 1, the data output circuit includes a DLL circuit 1, a data output clock signal generating unit 2, a pre-driver 3, a main driver 4, and a data pad 5. The DLL circuit 1 outputs a rising clock signal ‘rclk’ and a falling clock signal ‘fclk’. The data output clock signal generating unit 2 receives the rising clock signal ‘rclk’ and the falling clock signal ‘fclk’ and generates a rising data output clock signal ‘rclk_do’ and a falling data output clock signal ‘fclk_do’. A plurality of pre-drivers 3 are provided, each of which receives the rising data output clock signal ‘rclk_do’ the falling data output clock signal ‘fclk_do’, rising data signal ‘rdata’, and falling data signal ‘fdata’ and outputs driving data signal ‘drdata’. A plurality of main drivers 4 are provided, each of which drives the driving data signal ‘drdata’ to output output data signal ‘odata’. The output data signal ‘odata’ is output through the corresponding data pad 5.

FIG. 2 is a timing diagram illustrating the operation of a data output circuit of FIG. 1, and shows the waveforms of clock signals used in the data output circuit during a high frequency operation. Specifically, FIG. 2 shows the waveforms of the rising clock signal ‘rclk’, the falling clock signal ‘fclk’, the rising data output clock signal ‘rclk_do’ and the falling data output clock signal ‘fclk_do’.

Referring to FIG. 2, the rising clock signal ‘rclk’ and the falling clock signal ‘fclk’ have opposite phases. The rising data output clock signal ‘rclk_do’ must have an inverted phase of the rising clock signal ‘rclk’, and needs to have a high-level period that is shorter than that of the rising clock signal ‘rclk’. Similarly, the falling data output clock signal ‘fclk_do’ must have an inverted phase of the falling clock signal ‘fclk’ and needs to have a high-level period that is shorter than that of the falling clock signal ‘fclk’.

As the processing speed of conventional semiconductor memory apparatus increases, the frequency of the associated clock signal needs to increase, and the frequencies of the rising clock signal ‘rclk’ and the falling clock signal ‘fclk’ should also increase. However, delay elements for generating the rising data output clock signal ‘rclk_do’ and the falling data output clock signal ‘fclk_do’ have absolute delay values. Therefore, the rising data output clock signal ‘rclk_do’ and the falling data output clock signal ‘fclk_do’ each have a high-level period that is shorter than a low-level period only when the rising clock signal ‘rclk’ and the falling clock signal ‘fclk’ each have a lower frequency than a predetermined frequency relative to the clock signal frequency.

When the frequencies of the rising clock signal ‘rclk’ and the falling clock signal ‘fclk’ exceed the predetermined frequency, the high-level periods of the rising clock signal ‘rclk’ and the rising data output clock signal ‘rclk_do’ have the same width, as do the high-level periods of the falling clock signal ‘fclk’ and the falling data output clock signal ‘fclk_do’.

FIG. 2 shows the rising clock signal ‘rclk’ and the falling clock signal ‘fclk’ each having a frequency that is higher than the predetermined frequency. In this case, the rising data output clock signal ‘rclk_do’ and the falling data output clock signal ‘fclk_do’ have opposite phases. Therefore, the rising edge time of the rising data output clock signal ‘rclk_do’ overlaps the falling edge time of the falling data output clock signal ‘fclk_do’ as does the falling edge time of the rising data output clock signal ‘rclk_do’ and the rising edge time of the falling data output clock signal ‘fclk_do’. This causes errors during a data output operation.

Accordingly, a data output circuit in a conventional semiconductor memory apparatus has a problem in that as a high-frequency clock signal is used to improve the processing speed of the semiconductor memory apparatus, the high-level periods of the rising data output clock signal and the falling data output clock signal overlap each other, which results in low stability. The reason is that in a conventional data output circuit, when delay elements having a fixed delay value are used to generate a data output clock signal, the waveform of a DLL clock signal for a high-frequency operation is identical to the waveform of the data output clock signal.

### SUMMARY

A semiconductor memory apparatus capable of preventing errors, such as the output of undesirable data during a high speed operation is described herein.

In one aspect, a data output circuit includes a data output clock signal generating unit configured to generate a rising data output clock signal and a rising latch signal from a rising clock signal in response to a falling latch signal, and to generate a falling data output clock signal and the falling latch signal from a falling clock signal in response to the rising latch signal, and a data output pre-driver configured to drive a rising data signal in response to the rising data output clock signal and to drive a falling data in response to the falling data output clock signal.

In another aspect, a data output circuit includes a pulse generating section configured to adjust the pulse widths of a rising clock signal and a falling clock signal, thereby generating a rising pulse signal and a falling pulse signal, respectively, a latch section configured to alternately use signals generated from the rising pulse signal and the falling pulse signal as latch signals, thereby generating a rising data output clock signal and a falling data output clock signal, respectively, a control clock signal generating section configured to alternately use signals generated from the rising data output clock signal and the falling data output clock signal as period control signals, thereby generating a rising control clock signal and a falling control clock signal, and a pre-driving section configured to drive a rising data and a falling data in response to the rising control clock signal and the falling control clock signal, respectively.

These and other features, aspects, and embodiments are described below in the section entitled “Detailed Description.”

### BRIEF DESCRIPTION OF THE DRAWINGS

Features, aspects, and embodiments are described in conjunction with the attached drawings, in which:

FIG. 1 is a block diagram illustrating an exemplary data output circuit.

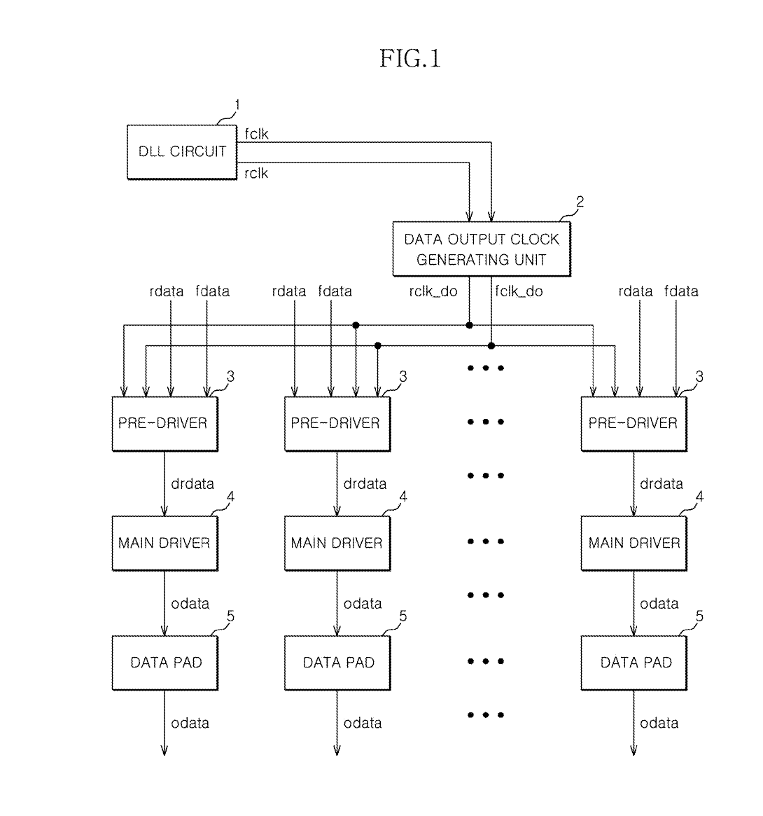

FIG. 2 is a timing diagram illustrating the operation of the data output circuit of FIG. 1.

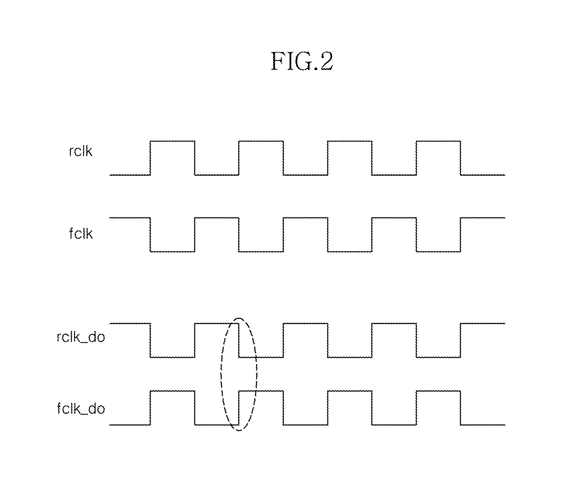

FIG. 3 is a block diagram illustrating a data output circuit according to one embodiment.

FIG. 4 is a diagram illustrating a detailed structure of data output clock signal generating unit that can be included in the circuit shown in FIG. 3.

FIG. 5 is a diagram illustrating a detailed structure of a first inverting delayer that can be included in the unit shown in FIG. 4.

FIG. 6 is a diagram illustrating a detailed structure of a data output pre-driver that can be included in the circuit shown in FIG. 3.

FIG. 7 is a timing diagram illustrating the operation of the data output circuit shown in FIG. 3.

FIG. 8 is a diagram illustrating a fuse circuit that can be used to control the data output circuit of FIG. 3.

FIG. 9 is a diagram illustrating a structure of a data output clock signal generating unit using the fuse circuit shown in FIG. 8.

### DETAILED DESCRIPTION

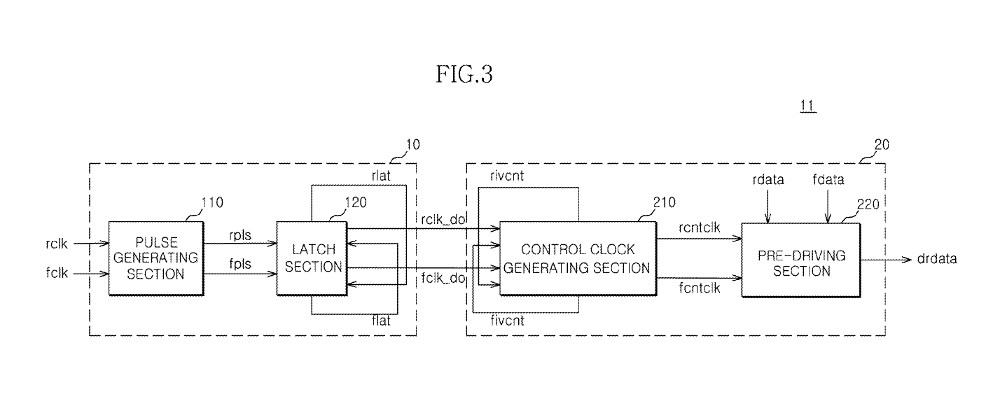

FIG. 3 is a diagram illustrating an example data output circuit 11 according to one embodiment. Referring to FIG. 3, the data output circuit 11 can include a data output clock signal generating unit 10 and a data output pre-driver 20.

The data output clock signal generating unit 10 can be configured to generate a rising data output clock signal ‘rclk_do’ and a rising latch signal ‘rlat’ from a rising clock signal ‘rclk’ in response to a falling latch signal ‘flat’, and to generate a falling data output clock signal ‘fclk_do’ and the falling latch signal ‘flat’ from a falling clock signal ‘fclk’ in response to the rising latch signal ‘rlat’.

The data output clock signal generating unit 10 can include a pulse generating section 110 and a latch section 120. The pulse generating section 110 can be configured to adjust the pulse widths of the rising clock signal ‘rclk’ and the falling clock signal ‘fclk’, thereby generating a rising pulse signal ‘rpls’ and a falling pulse signal ‘frpls’, respectively. The latch section 120 can be configured to generate the rising data output clock signal ‘rclk_do’ and the rising latch signal ‘rlat’ from the rising pulse signal ‘rpls’ in response to the falling latch signal ‘flat’, and to generate the falling data output clock signal ‘fclk_do’ and the falling latch signal ‘flat’ from the falling pulse signal ‘frpls’ in response to the rising latch signal ‘rlat’.

The data output pre-driver 20 can be configured to drive a rising data ‘rdata’ in response to the rising data output clock signal ‘rclk_do’, and to drive a falling data ‘fdata’ in response to the falling data output clock signal ‘fclk_do’.

The data output pre-driver 20 can include a control clock signal generating section 210 and a pre-driving section 220. The control clock signal generating section 210 can be configured to generate a rising period control signal ‘rivcnt’ and a rising control clock signal ‘rcntclk’ in response to the rising data output clock signal ‘rclk_do’ and a falling period control signal ‘fivcnt’, and to generate the falling period control signal ‘fivcnt’ and a falling control clock signal ‘fcntclk’ in response to the falling data output clock signal ‘fclk_do’ and the rising period control signal ‘rivcnt’. The pre-driving section 220 can be configured to drive the rising data ‘rdata’ in response to the rising control clock signal ‘rcntclk’, and to drive the falling data ‘fdata’ in response to the falling control clock signal ‘fcntclk’, thereby outputting driving data ‘drdata’.

In a conventional circuit, the rising pulse signal ‘rpls’ and the falling pulse signal ‘frpls’ are inverted and used as a rising data output clock signal ‘rclk_do’ and a falling data output clock signal ‘fclk_do’, respectively. In contrast, according to the embodiments described herein, the rising pulse signal ‘rpls’ can be latched by the falling latch signal ‘flat’ and can then be used as the rising data output clock signal ‘rclk_do’. The falling pulse signal ‘frpls’ can be latched by the rising latch signal ‘rlat’ and can then be used as the falling data output clock signal ‘fclk_do’.

The rising pulse signal ‘rpls’ and the falling pulse signal ‘frpls’ can be toggled in the form of a low pulse, respectively. Each of the levels of the falling data output clock signal ‘fclk_do’ and the rising data output clock signal ‘rclk_do’ can be kept at a predetermined level, and change to a different level when the rising pulse signal ‘rpls’ or the falling pulse signal ‘frpls’ are toggled. In this way, the periods in which the rising data output clock signal ‘rclk_do’ and the falling data output clock signal ‘fclk_do’ are high are longer than low level periods.

The rising period control signal ‘rivcnt’ and the falling period control signal ‘fivcnt’ can have opposite phases of the rising data output clock signal ‘rclk_do’ and the falling data output clock signal ‘fclk_do’ respectively. The rising control clock signal ‘rcntclk’ can be generated from the rising data output clock signal ‘rclk_do’ under the control of the falling period control signal ‘fivcnt’, and the falling control clock signal ‘fcntclk’ can be generated from the falling data output clock signal ‘fclk_do’ under the control of the rising period control signal ‘rivcnt’. In this way, the rising control clock signal ‘rcntclk’ and the falling control clock signal ‘fcntclk’ can each have a high-level period that is shorter than a low-level period.

Thereafter, the pre-driving section 220 can be configured to use the rising control clock signal ‘rcntclk’ to drive the rising data ‘rdata’, and to use the falling control clock signal ‘fcntclk’ to drive the falling data ‘fdata’. In this case, since the rising control clock signal ‘rcntclk’ and the falling control clock signal ‘fcntclk’ each have a high-level period that is shorter than a low-level period, there is no overlapping portion there between.

Therefore, undesirable data output during high frequency operation can be prevented. In other words, the rising latch signal ‘rlat’ and the falling latch signal ‘flat’ can alternately be used as latch signals to generate the rising data output clock signal ‘rclk_do’ and the falling data output clock signal ‘fclk_do’, and the rising period control signal ‘rivcnt’ and the falling period control signal ‘fivcnt’ can alternately be used as signals for controlling the high-level period of clock signals to generate the rising control clock signal ‘rcntclk’ and the falling control clock signal ‘fcntclk’. As a result, it is possible to stabilize a data output operation.

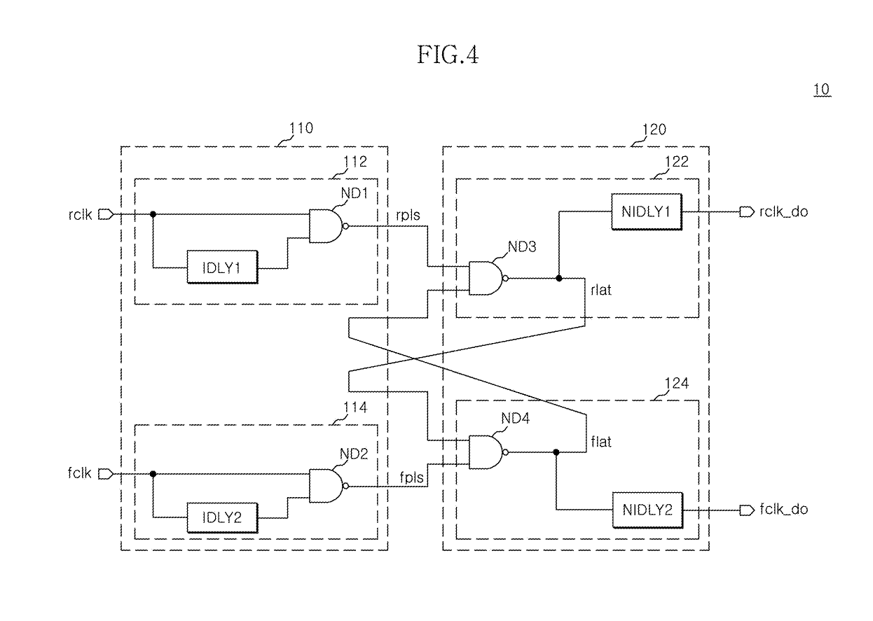

More specifically, as shown in FIG. 4, the pulse generating section 110 can include a rising pulse generator 112 and a falling pulse generator 114.

The rising pulse generator 112 can be configured to adjust the pulse width of the rising clock signal ‘rclk’, thereby generating the rising pulse signal ‘rpls’. The rising pulse generator 112 can include a first inverting delayer IDLY1 that can be configured to receive the rising clock signal ‘rclk’, and a first NAND gate ND1 that can be configured to receive the rising clock signal ‘rclk’ and an output signal of the first inverting delayer IDLY1 and to output the rising pulse signal ‘rpls’.

The falling pulse generator 114 can be configured to adjust the pulse width of the falling clock signal ‘fclk’, thereby generating the falling pulse signal ‘frpls’. The falling pulse generator 114 can include a second inverting delayer IDLY2 that can be configured to receive the falling clock signal ‘fclk’, and a second NAND gate ND2 that can be configured to receive the falling clock signal ‘fclk’ and an output signal of the second inverting delayer IDLY2, and to output the falling pulse signal ‘frpls’.

The latch section 120 can include a rising latch 122 and a falling latch 124. The rising latch 122 can be configured to generate the rising data output clock signal ‘rclk_do’ and the rising latch signal ‘rlat’ from the rising pulse signal ‘rpls’ in response to the falling latch signal ‘flat’. The rising latch 122 can include a third NAND gate ND3 that can be configured to receive the rising pulse signal ‘rpls’ and the falling latch signal ‘flat’, and to output the rising latch signal ‘rlat’, and a non-inverting delayer NIDLY1 that can be configured to receive the rising latch signal ‘rlat’, and to output the rising data output clock signal ‘rclk_do’.

The falling latch 124 can be configured to generate the falling data output clock signal ‘fclk_do’ and the falling latch signal ‘flat’ from the falling pulse signal ‘frpls’ in response to the rising latch signal ‘rlat’. The falling latch 124 can include a fourth NAND gate ND4 that can be configured to receive the falling pulse signal ‘frpls’ and the rising latch signal ‘rlat’, and to output the falling latch signal ‘flat’, and a second non-inverting delayer NIDLY2 that can be configured to receive the falling latch signal ‘flat’, and to output the falling data output clock signal ‘fclk_do’.

In the data output clock signal generating unit 10 having the above-mentioned structure, the level of the rising data output clock signal ‘rclk_do’ can change due to falling edges of the rising pulse signal ‘rpls’ and the falling pulse signal ‘frpls’. The rising data output clock signal ‘rclk_do’ is not affected by the rising edges of the rising pulse signal ‘rpls’ and the falling pulse signal ‘frpls’. The level of the falling data output clock signal ‘fclk_do’ changes due to falling edges of the falling pulse signal ‘frpls’ and the rising pulse signal ‘rpls’, but the falling data output clock signal ‘fclk_do’ is not affected by the rising edges of the falling pulse signal ‘frpls’ and the rising pulse signal ‘rpls’.

That is, the rising data output clock signal ‘rclk_do’ has a rising edge under the influence of the falling edge time of the rising pulse signal ‘rpls’, and has a falling edge under the influence of the falling edge time of the falling pulse signal ‘frpls’. In this embodiment, the latch section 120 can be configured such that the time when an influence of the change in the level of the falling pulse signal ‘frpls’ is transmitted to the first non-inverting delayer NIDLY1 that outputs the rising data output clock signal ‘rclk_do’ is longer than the time when an influence of the change in the level of the rising pulse signal ‘rpls’ is transmitted to the first non-inverting delayer NIDLY1. Therefore, the rising data output clock signal ‘rclk_do’ can have a high-level period that is longer than a low-level period. Similarly, the falling data output clock signal ‘fclk_do’ can have a high-level period that is longer than a low-level period.

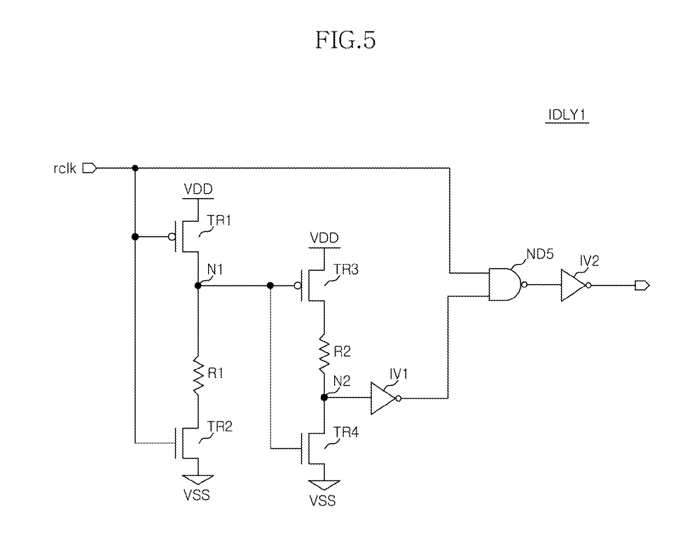

FIG. 5 shows the structure of the first inverting delayer IDLY1 shown in FIG. 4 in accordance with one embodiment. Since the first inverting delayer IDLY1 and the second inverting delayer IDLY2 can have the same structure, only the first inverting delayer IDLY1 will be described below for the convenience of explanation.

The first inverting delayer IDLY1 can include a first transistor TR1, a second transistor TR2, a third transistor TR3, a fourth transistor TR4, a first resistor R1, a second resistor R2, a first inverter IV1, a second inverter IV2, and a fifth NAND gate ND5.

The first transistor TR1 can have a gate’ which receives the rising clock signal ‘rclk’, a source can be configured to receive an external power supply voltage VDD, and a drain coupled with a first node N1. The first resistor R1 can have one end coupled with the first node N1 and the other end coupled with the drain of the second transistor TR2. The second transistor TR2 can have a gate, which receives the rising clock signal ‘rclk’, and a source which is grounded.

The third transistor TR3 can have a gate coupled with the first node N1, and a source can be configured to receive the external power supply voltage VDD. The second resistor R2 can have one end coupled with the drain of the third transistor TR3 and the other end coupled with a second node N2. The fourth transistor TR4 can have a gate coupled with the first node N1, a drain coupled with the second node N2, and a source that is grounded.

The first inverter IV1 can be configured to receive a voltage applied at the second node N2. The fifth NAND gate ND5 can be configured to receive the rising clock signal ‘rclk’ and an output signal of the first inverter IV1. The second inverter IV2 can be configured to receive an output signal of the fifth NAND gate ND5.

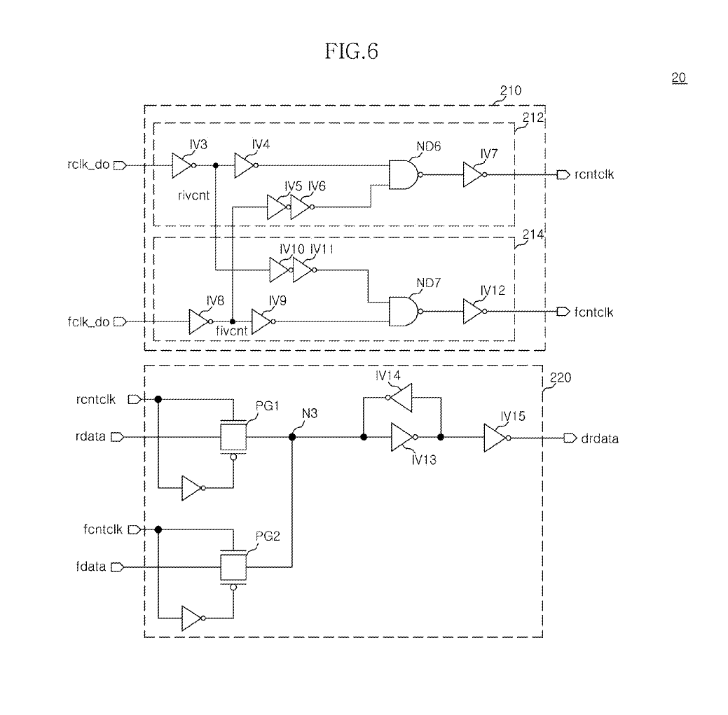

Referring to FIG. 6, the data output pre-driver 20 can include the control clock signal generating section 210 and the pre-driving section 220. The control clock signal generating section 210 can include a rising control clock signal generator 212 and a falling control clock signal generator 214.

The rising control clock signal generator 212 can be configured to generate the rising period control signal ‘rivcnt’ and the rising control clock signal ‘rcntclk’ in response to the rising data output clock signal ‘rclk_do’ and the falling period control signal ‘fivcnt’. The rising control clock signal generator 212 can include a third inverter IV3, a fourth inverter IV4, a fifth inverter IV5, a sixth inverter IV6, a seventh inverter IV7, and a sixth NAND gate ND6.

The third inverter IV3 can be configured to receive the rising data output clock signal ‘rclk_do’ and to output the rising period control signal ‘rivcnt’. The fourth inverter IV4 can be configured to receive the falling period control signal ‘fivcnt’. The fifth inverter IV5 and the sixth inverter IV6 non-inversely drive the falling period control signal ‘fivcnt’. The sixth NAND gate ND6 can be configured to receive an output signal of the fourth inverter IV4 and an output signal of the sixth inverter IV6. The seventh inverter IV7 can be configured to receive an output signal of the sixth NAND gate ND6 and outputs the rising control clock signal ‘rcntclk’.

The falling control clock signal generator 214 can be configured to generate the falling period control signal ‘fivcnt’ and the falling control clock signal ‘fcntclk’ in response to the falling data output clock signal ‘fclk_do’ and the rising period control signal ‘rivcnt’. The falling control clock signal generator 214 can include an eighth inverter IV8, a ninth inverter IV9, a tenth inverter IV10, an eleventh inverter IV11, and a twelfth inverter IV12.

The eighth inverter IV8 can be configured to receive the falling data output clock signal ‘fclk_do’ and to output the falling period control signal ‘fivcnt’. The ninth inverter IV9 can be configured to receive the rising period control signal ‘rivcnt’. The tenth inverter IV10 and the eleventh inverter IV11 non-inversely drive the rising period control signal ‘rivcnt’. The twelfth inverter IV12 can be configured to receive an output signal of the ninth inverter IV9 and an output signal of the eleventh inverter IV11, and to output the falling control clock signal ‘fcntclk’.

The pre-driving section 220 can include a first pass gate PG1, a second pass gate PG2, a thirteenth inverter IV13, a fourteenth inverter IV14, and a fifteenth inverter IV15.

The first pass gate PG1 can be configured to transmit the rising data ‘rdata’ to a third node N3 under the control of the rising control clock signal ‘rcntclk’. The second pass gate PG2 can be configured to transmit the falling data ‘fdata’ to the third node N3 under the control of the falling control clock signal ‘fcntclk’. The thirteenth inverter IV13 can be configured to receive the signal transmitted to the third node N3. The fourteenth inverter IV14 and the thirteenth inverter IV13 form a latch structure. The fifteenth inverter IV15 can be configured to receive an output signal of the thirteenth inverter IV13 and outputs the driving data ‘drdata’.

The rising data ‘rdata’ and the falling data ‘fdata’ are latched at a predetermined level.

In the data output pre-driver 20 having the above-mentioned structure, the rising period control signal ‘rivcnt’ can have an opposite phase of the rising data output clock signal ‘rclk_do’. Similarly, the falling period control signal ‘fivcnt’ can have an opposite phase of the falling data output clock signal ‘fclk_do’. The rising control clock signal ‘rcntclk’ can have a waveform that is obtained by performing an AND operation on the rising data output clock signal ‘rclk_do’ and the falling period control signal ‘fivcnt’ and delaying the operated signal. Therefore, the rising control clock signal ‘rcntclk’ can have a high-level period that is shorter than a low-level period. Similarly, the falling control clock signal ‘fcntclk’ can be generated from the falling data output clock signal ‘fclk_do’ and the rising period control signal ‘rivcnt’, and can have a high-level period that is shorter than a low-level period.

That is, the high-level period of the rising control clock signal ‘rcntclk’ does not overlap the high-level period of the falling control clock signal ‘fcntclk’. Therefore, when the rising data ‘rdata’ is driven by the rising control clock signal ‘rcntclk’ and the falling data ‘fdata’ is driven by the falling control clock signal ‘fcntclk’, no error occurs, that is, undesirable data is not output.

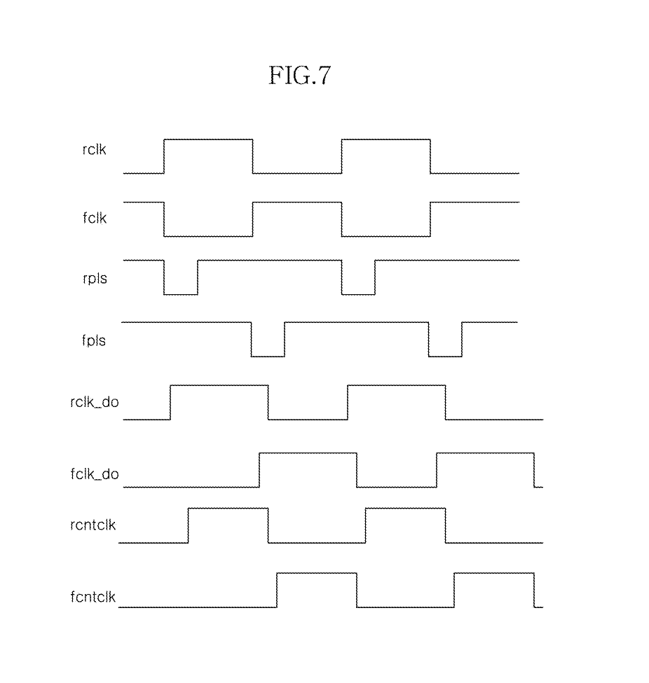

FIG. 7 shows the rising clock signal ‘rclk’, the falling clock signal ‘fclk’, the rising pulse signal ‘rpls’, the falling pulse signal ‘frpls’, the rising data output clock signal ‘rclk_do’, the falling data output clock signal ‘fclk_do’ the rising control clock signal ‘rcntclk’, and the falling control clock signal ‘fcntclk’.

As can be seen from FIG. 7, the rising pulse signal ‘rpls’ is a low-pulse signal that is generated from the rising clock signal ‘rclk’, and the falling pulse signal ‘frpls’ is a low-pulse signal that is generated from the falling clock signal ‘fclk’. In this embodiment, the rising pulse signal ‘rpls’ and the falling pulse signal ‘frpls’ each have a fixed pulse width. Therefore, when a semiconductor memory apparatus operates at a high speed, the rising pulse signal ‘rpls’ and the falling pulse signal ‘frpls’ have the same waveforms as the rising clock signal ‘rclk’ and the falling clock signal ‘fclk’, respectively. However, the rising data output clock signal ‘rclk_do’ and the falling data output clock signal ‘fclk_do’ each have a high-level period that is longer than a low-level period, and the rising control clock signal ‘rcntclk’ and the falling control clock signal ‘fcntclk’ each have a high-level period that is shorter than a low-level period. Therefore, the high-level period of the rising control clock signal ‘rcntclk’ does not overlap the high-level period of the falling control clock signal ‘fcntclk’ . As a result, in the semiconductor memory apparatus that operates at a high speed, a rising data and a falling data can be alternately driven.

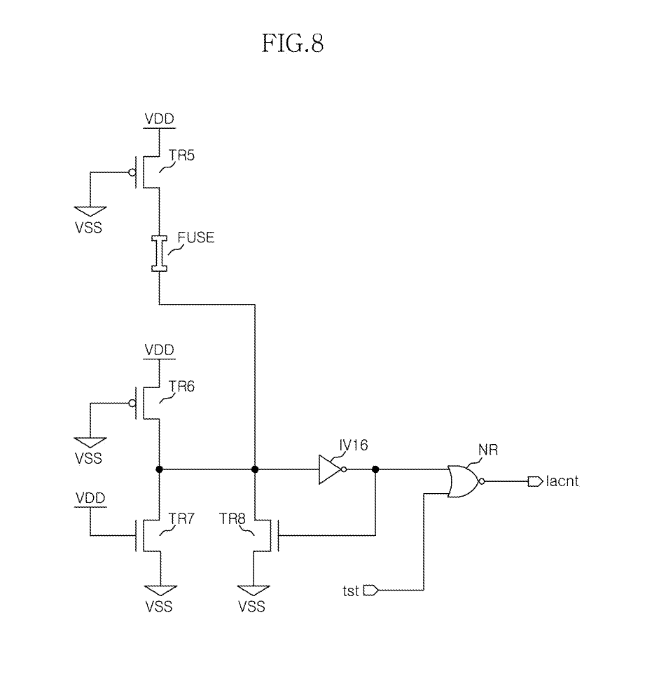

FIG. 8 shows that the data output circuit 11 can be controlled by using a test mode or a fuse option.

The fuse circuit shown in FIG. 8 can include a fifth transistor TR5, a sixth transistor TR6, a seventh transistor TR7, an eighth transistor TR8, a sixteenth inverter IV16, a fuse option FUSE, and a NOR gate NR.

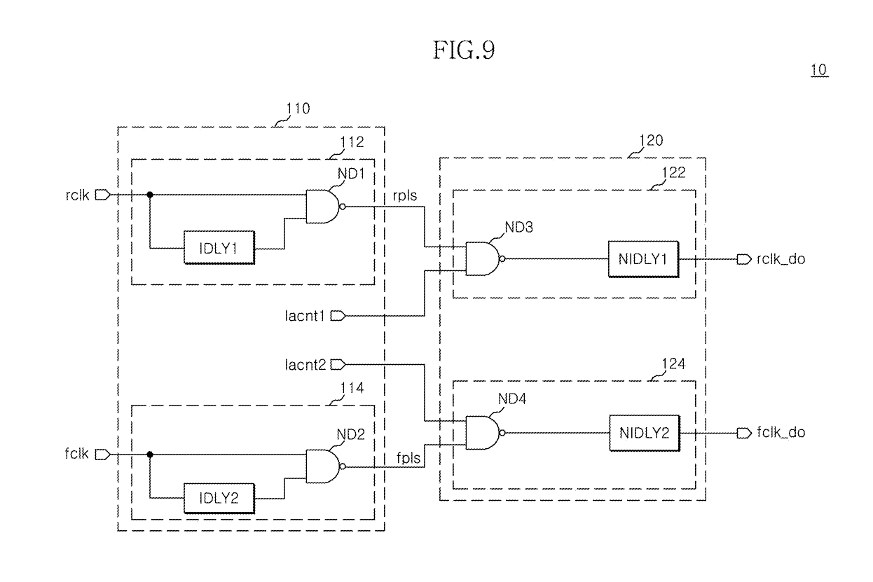

The NOR gate NR can be configured to receive a test signal ‘tst’ and a signal whose voltage level can be determined by controlling the fuse option FUSE. When the test signal ‘tst’ is enabled or the fuse option FUSE is cut, a latch control signal ‘lacnt’ is enabled at a low level. The latch control signal ‘lacnt’ can be replaced with the rising latch signal ‘rlat’ or the falling latch signal ‘flat’. In this case, when the latch signal ‘lat’ is disabled, the data output clock signal generating unit 10 can be configured to perform the same operation as in a conventional circuit. This structure is shown in FIG. 9. FIG. 9 shows that, in the data output clock signal generating unit 10 shown in FIG. 4, the falling latch signal ‘flat’ and the rising latch signal ‘rlat’ are replaced with a first latch control signal ‘lacnt1’ and a second latch control signal ‘lacnt2’ generated by two fuse circuits, respectively.

When the third NAND gate ND3 and the fourth NAND gate ND4 of the data output clock signal generating unit 10 shown in FIG. 9 receive the latch control signal ‘lacnt’ in addition to two existing signals, the data output clock signal generating unit 10 can be affected by the test signal ‘tst’ or the cutting of the fuse option FUSE. That is, the operation of the data output clock signal generating unit 10 can be adjusted according to the test mode or the fuse option.

As described above, the data output circuit 11 according to the embodiments described herein can be configured to generate a rising pulse signal and a falling pulse signal from a rising clock signal and a falling clock signal, respectively, and to generate a rising data output clock signal and a falling data output clock signal from the rising pulse signal and the falling pulse signal, respectively. In this case, the data output circuit can be configured to latche the rising data output clock signal and the falling data output clock signal using, for example, a flip-flop such that the rising data output clock signal and the falling data output clock signal each have a high-level period that is longer than a low-level period. Then, the data output circuit 11 uses the rising data output clock signal and the falling data output clock signal to generate a rising control clock signal and a falling control clock signal each having a low-level period that is longer than a high-level period. Since a rising data and a falling data are driven by the rising control clock signal and the falling control clock signal having the above-mentioned characteristics, it is possible to improve the stability of a data output operation. Therefore, it is possible to prevent an erroneous operation due to a high-frequency clock signal during a high-speed operation, and thus improve the processing speed of a semiconductor memory apparatus.

While certain embodiments have been described above, it will be understood that the embodiments described are by way of example only. Accordingly, the apparatus and methods described herein should not be limited based on the described embodiments. Rather, the apparatus and methods described herein should only be limited in light of the claims that follow when taken in conjunction with the above description and accompanying drawings.

What is claimed is:

1. A data output circuit of a semiconductor memory apparatus, comprising:
a data output clock signal generating unit configured to generate a rising data output clock signal and a rising latch signal from a rising clock signal in response to a falling latch signal, and to generate a falling data output clock signal and the falling latch signal from a falling clock signal in response to the rising latch signal; and
a data output pre-driver configured to drive a rising data signal in response to the rising data output clock signal, and to drive a falling data in response to the falling data output clock signal.

2. The data output circuit of claim 1, wherein the data output clock signal generating unit is further configured to generate a rising pulse signal from the rising clock signal and to generate a falling pulse signal from the falling clock signal, and to generate the rising data output clock signal and the falling data output clock signal, the levels of which change when the rising pulse signal or the falling pulse signal is toggled.

3. The data output circuit of claim 2, wherein the data output clock signal generator is configured to generate the rising data output clock signal and the falling data output clock signal each having a first level period that is longer than a second level period.

4. The data output circuit of claim 3, wherein the data output clock signal generating unit comprises:
a pulse generating section configured to adjust the pulse widths of the rising clock signal and the falling clock signal, thereby generating a rising pulse signal and a falling pulse signal, respectively; and
a latch section configured to generate the rising data output clock signal and a rising latch signal from the rising pulse signal in response to the falling latch signal, and to generate the falling data output clock signal and a falling latch signal from the falling pulse signal in response to the rising latch signal.

5. The data output circuit of claim 4, wherein the pulse generating section comprises:
a rising pulse generator configured to adjust the pulse width of the rising clock signal, thereby generating the rising pulse signal; and
a falling pulse generator configured to adjust the pulse width of the falling clock signal, thereby generating the falling pulse signal.

6. The data output circuit of claim 4, wherein the latch section comprises:
a rising latch configured to generate the rising data output clock signal and the rising latch signal from the rising pulse signal in response to the falling latch signal; and
a falling latch configured to generate the falling data output clock signal and the falling latch signal from the falling pulse signal in response to the rising latch signal.

7. The data output circuit of claim 1, wherein the data output pre-driver is further configured to generate a rising period control signal from the rising data output clock signal, and to generate a falling period control signal from the falling data output clock signal, and to generate a rising control clock signal from the rising data output clock signal under the control of the falling period control signal, and to generate a falling control clock signal from the falling data output clock signal under the control of the rising period control signal.

8. The data output circuit of claim 7, wherein the data output pre-driver is further configured to generate the rising control clock signal and the falling control clock signal each having a first level period that is shorter than a second level period, and to control the driving of the rising data and the falling data.

9. The data output circuit of claim 8, wherein the data output pre-driver comprises:
a control clock signal generating section configured to generate a rising period control signal and the rising control clock signal in response to the rising data output clock signal and the falling period control signal, and to generate the falling period control signal and the falling control clock signal in response to the falling data output clock signal and the rising period control signal; and
a pre-driving section configured to drive the rising data in response to the rising control clock signal, and to drive the falling data in response to the falling control clock signal.

10. The data output circuit of claim 9, wherein the control clock signal generating section comprises:
a rising control clock signal generator configured to generate the rising period control signal and the rising control clock signal in response to the rising data output clock signal and the falling period control signal; and
a falling control clock signal generator configured to generate the falling period control signal and the falling control clock signal in response to the falling data output clock signal and the rising period control signal.

11. A data output circuit of a semiconductor memory apparatus, comprising:
a pulse generating section configured to adjust the pulse widths of a rising clock signal and a falling clock signal, thereby generating a rising pulse signal and a falling pulse signal, respectively;
a latch section configured to alternately use signals generated from the rising pulse signal and the falling pulse signal as latch signals, thereby generating a rising data output clock signal and a falling data output clock signal, respectively;
a control clock signal generating section configured to alternately use signals generated from the rising data output clock signal and the falling data output clock signal as period control signals, thereby generating a rising control clock signal and a falling control clock signal; and
a pre-driving section configured to drive a rising data and a falling data in response to the rising control clock signal and the falling control clock signal, respectively.

12. The data output circuit of claim 11, wherein the pulse generating section comprises:
a rising pulse generator configured to adjust the pulse width of the rising clock signal, thereby generating the rising pulse signal; and
a falling pulse generator configured to adjust the pulse width of the falling clock signal, thereby generating the falling pulse signal.

13. The data output circuit of claim 11, wherein the latch section is further configured to generate the rising data output clock signal and the falling data output clock signal each of which has a first level period that is longer than a second level period and whose levels are changed when the rising pulse signal or the falling pulse signal is toggled.

14. The data output circuit of claim 13, wherein the latch section comprises:
a rising latch configured to generate the rising data output clock signal and a rising latch signal from the rising pulse signal in response to a falling latch signal; and
a falling latch configured to generate the falling data output clock signal and the falling latch signal from the falling pulse signal in response to the rising latch signal.

15. The data output circuit of claim 11, wherein the control clock signal generating section is further configured to generate a rising period control signal from the rising data output clock signal, and to generate a falling period control signal from the falling data output clock signal, and to generate a rising control clock signal from the rising data output clock signal under the control of the falling period control signal, and to generate a falling control clock signal from the falling data output clock signal under the control of the rising period control signal.

16. The data output circuit of claim 15, wherein the control clock signal generating section is further configured to generate the rising control clock signal and the falling control clock signal each having a first level period that is shorter than a second level period.

17. The data output circuit of claim 16, wherein the control clock signal generating section comprises:
a rising control clock signal generator configured to generate the rising period control signal and the rising control clock signal in response to the rising data output clock signal and the falling period control signal; and
a falling control clock signal generator configured to generate the falling period control signal and the falling control clock signal in response to the falling data output clock signal and the rising period control signal.
